(19) United States
(12) Patent Application Publication
(10) Pub. No.: US 2012/0326338 A1
(43) Pub. Date: Dec. 27, 2012

(54) SEMICONDUCTOR DEVICE

(75) Inventors: Toyokazu EGUCHI, Tokyo (JP); Manabu Matsumoto, Kanagawa (JP); Isao Ozawa, Kanagawa (JP)

(73) Assignee: Kabushiki Kaisha Toshiba, Tokyo (JP)

(21) Appl. No.: 13/534,453

(22) Filed: Jun. 27, 2012

(30) Foreign Application Priority Data
Jun. 27, 2011 (JP) 2011-142231
Mar. 26, 2012 (JP) 2012-069503

(51) Int. Cl. H01L 23/52

(52) U.S. Cl. 257/786; 257/E23.141

(57) ABSTRACT

According to one embodiment, a semiconductor device is provided which includes a substrate in which conductor layers and insulated layers are stacked alternately, a semiconductor element mounted on a first surface side of the substrate, and a reinforcing plate attached to a second surface side that is an opposite side of the first surface of the substrate.

### CROSS-REFERENCE TO RELATED APPLICATIONS

This application is based upon and claims the benefit of priority from Japanese Patent Application No. 2011-142231, filed on Jun. 27, 2011, and the prior Japanese Patent Application No. 2012-069503, filed on Mar. 26, 2012; the entire contents of all of which are incorporated herein by reference.

### FIELD

Embodiments described herein relate generally to a semiconductor device.

### BACKGROUND

A semiconductor device, in which nonvolatile semiconductor memory elements, such as a NAND flash memory, and volatile semiconductor memory elements, such as a DRAM, are mounted on a substrate, has been used. Recently, the size and thickness of the semiconductor device have been reduced. Further reduction in size and thickness is required in such a semiconductor device.

### BRIEF DESCRIPTION OF THE DRAWINGS

FIG. 1 is a block diagram illustrating a configuration example of a semiconductor device according to a first embodiment;

FIG. 2 is a plan view illustrating a schematic configuration of the semiconductor device;

FIG. 3 is a cross-sectional view along line A-A shown in FIG. 2;

FIG. 4 is a plan view illustrating a schematic configuration of a semiconductor device according to a second embodiment;

FIG. 5 is a cross-sectional view along line B-B shown in FIG. 4;

FIG. 6 is a cross-sectional view along line B-B shown in FIG. 4 and is a diagram illustrating a state where an external force is applied to the semiconductor device;

FIG. 7 is a transverse sectional view of a semiconductor device according to a first modified example of the second embodiment;

FIG. 8 is a partial enlarged view of a portion C shown in FIG. 7 and is a diagram exemplifying a state where an external force is not applied to the semiconductor device;

FIG. 9 is a partial enlarged view of the portion C shown in FIG. 7 and is a diagram exemplifying a state where an external force is applied to the semiconductor device;

FIG. 10 is a transverse sectional view of a semiconductor device according to a second modified example of the second embodiment;

FIG. 11 is a transverse sectional view of a semiconductor device according to a third modified example of the second embodiment;

FIG. 12 is an appearance perspective view of a semiconductor device according to a third embodiment;

FIG. 13 is an appearance perspective view of the semiconductor device shown in FIG. 12 and is a diagram illustrating a state where a guard is bent;

FIG. 14 is a transverse sectional view of the semiconductor device shown in FIG. 12;

FIG. 15 is a side view of the semiconductor device shown in FIG. 12;

FIG. 16 is an exploded perspective view of a semiconductor device according to a first modified example of the third embodiment;

FIG. 17 is an appearance perspective view of a semiconductor device according to a second modified example of the third embodiment;

FIG. 18 is an appearance perspective view of the semiconductor device shown in FIG. 17 and is a diagram illustrating a state where the guard is bent;

FIG. 19 is an appearance perspective view of a semiconductor device according to a third modified example of the third embodiment;

FIG. 20 is an appearance perspective view of a semiconductor device according to a fourth embodiment;

FIG. 21 is a perspective view of the semiconductor device shown in FIG. 20 viewed from a second surface side;

FIG. 22 is a diagram for explaining a relationship between a layer configuration of a substrate and its thickness; and

FIG. 23 is a partial enlarged cross-sectional view in which a portion on which a chip part is mounted is enlarged.

### DETAILED DESCRIPTION

In general, according to one embodiment, a semiconductor device is provided which includes a substrate in which conductor layers and insulated layers are stacked alternately, a semiconductor element mounted on a first surface side of the substrate, and a reinforcing plate attached to a second surface side that is an opposite side of the first surface of the substrate.

Exemplary embodiments of a semiconductor device will be explained below in detail with reference to the accompanying drawings. The present invention is not limited to the following embodiments.

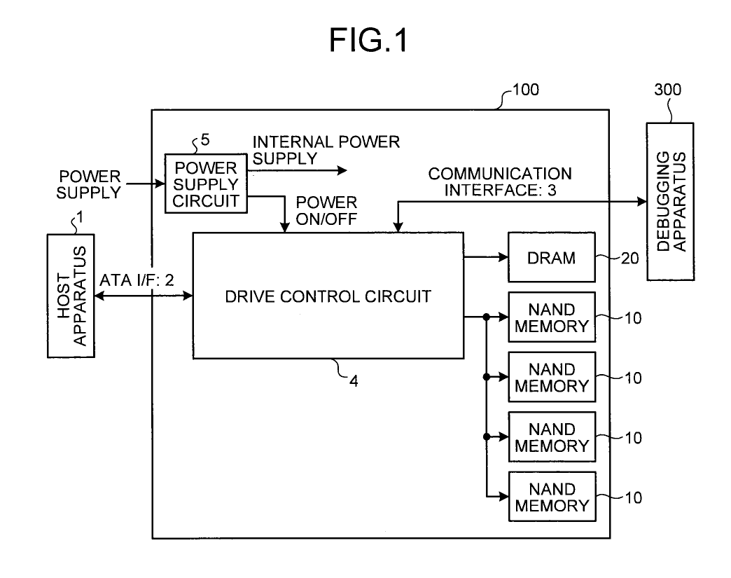

FIG. 1 is a block diagram illustrating a configuration example of a semiconductor device according to a first embodiment. A semiconductor device 100 is connected to a host apparatus (hereinafter, host) 1, such as a personal computer or a CPU core, via a memory connection interface, such as a SATA interface (SATA I/F) 2 and functions as an external memory of the host 1. Examples of the host 1 include a CPU of a personal computer and a CPU of an imaging device, such as a still camera and a video camera. The semiconductor device 100 can transmit and receive data to and from a debugging apparatus 300 via a communication interface 3, such as an RS232C interface (RS232C I/F).

The semiconductor device 100 includes NAND-type flash memories (hereinafter, abbreviated as NAND memories, semiconductor elements) 10 that are nonvolatile semiconductor memory elements, a drive control circuit 4 (semiconductor element) as a controller, a DRAM (semiconductor element) 20 that is a volatile semiconductor memory element capable of performing a storage operation faster than the NAND memory 10, and a power supply circuit 5.

The power supply circuit 5 generates a plurality of different internal DC power supply voltages from an external DC power supplied from a power supply circuit on the host 1 side and supplies these internal DC power supply voltages to respective circuits in the semiconductor device 100. The power supply circuit 5 detects a rising edge of an external power, generates a power-on reset signal, and supplies it to the drive control circuit 4.

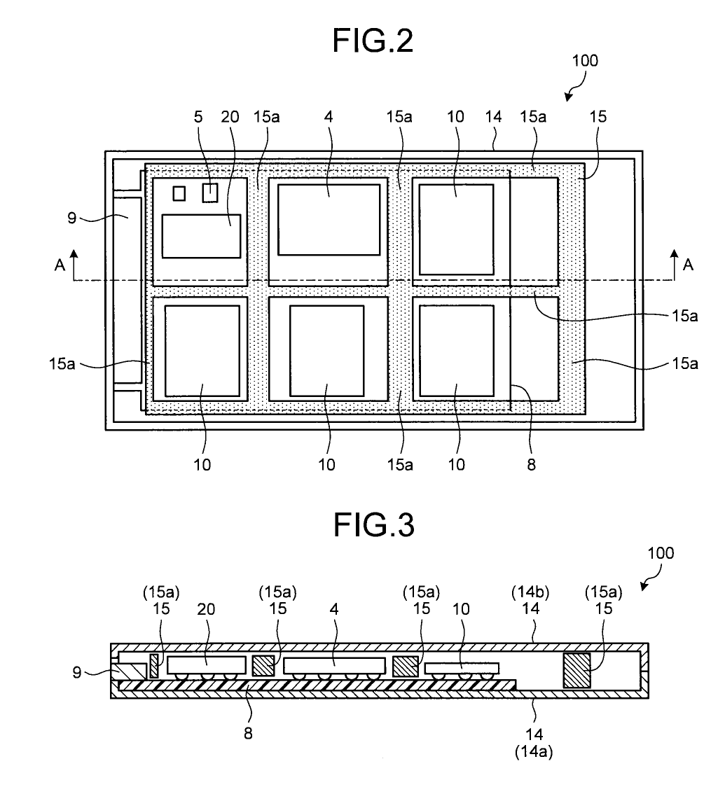

FIG. 2 is a plan view illustrating a schematic configuration of the semiconductor device 100. FIG. 3 is a cross-sectional view along line A-A shown in FIG. 2. The power supply circuit 5, the DRAM 20, the drive control circuit 4, and the NAND memories 10 are mounted on a first surface side of a substrate 8 on which wiring patterns are formed. The substrate 8 is stored in a case 14. The case 14 is composed of a lower case 14a and an upper case 14b.

The substrate 8 has an approximately rectangular shape in plan view. A connector 9, which is connected to the host 1 and functions as the SATA interface 2 and the communication interface 3 described above, is provided on a side of one shorter side of the substrate 8 having an approximately rectangular shape. The connector 9 functions as a power input unit that supplies power input from the host 1 to the power supply circuit 5. The connector 9 is, for example, an LIF connector.

The substrate 8 has a multilayer structure formed by stacking synthetic resin and, for example, has an eight-layer structure. The number of layers of the substrate 8 is not limited to eight. In the substrate 8, wiring patterns of various shapes are formed on the surface or the inner layer of each layer formed of synthetic resin. The power supply circuit 5, the DRAM 20, the drive control circuit 4, and the NAND memories 10 mounted on the substrate 8 are electrically connected to each other via the wiring patterns formed on the substrate 8.

A grid unit 15 formed by assembling columnar reinforcing units 15a having a columnar shape in a lattice shape is arranged on the first surface of the substrate 8. The columnar reinforcing units 15a are arranged to avoid mounted elements, such as the NAND memory 10, mounted on the first surface of the substrate 8. That means that the columnar reinforcing units 15a are arranged to pass through the gaps between the mounted elements, such as the NAND memory 10.

The columnar reinforcing units 15a are arranged to pass through the gaps between the mounted elements in such a manner, therefore, as shown in FIG. 3, it is possible to effectively use the space in the case and prevent the height of the semiconductor device 100 from increasing by providing the grid unit 15.

Moreover, the mechanical strength of the semiconductor device 100 can be improved by arranging the grid unit 15 on the first surface of the substrate 8. Therefore, even when the size and thickness of the semiconductor device 100 are reduced, it is possible to obtain the semiconductor device 100 that is not easily damaged by an external force or the like. For example, even when the semiconductor device 100 is a so-called card shaped semiconductor device 100 in which the planar shape of the case 14 has a size of 86 mm×54 mm and which has a height of 2.2 mm or lower, the semiconductor device 100 that is not easily damaged can be obtained by improving the mechanical strength by the grid unit 15.

Especially, a portion, in which the NAND memory 10 or the like is not arranged, in the substrate 8 tends to have a lower mechanical strength than a portion, in which the NAND memory 10 or the like is arranged, however, the grid unit 15 can effectively reinforce the portion whose mechanical strength tends to be low. Moreover, it is sufficient to arrange the grid unit 15 on the first surface of the substrate 8, therefore, the workability does not deteriorate and an increase in the manufacturing cost can be suppressed. Because a portion along the periphery of the semiconductor device 100 can easily ensure strength in a peripheral portion of the case 14, the grid unit 15 may be configured in a state where the columnar reinforcing units 15a provided in a portion along the periphery of the semiconductor device 100 are omitted.

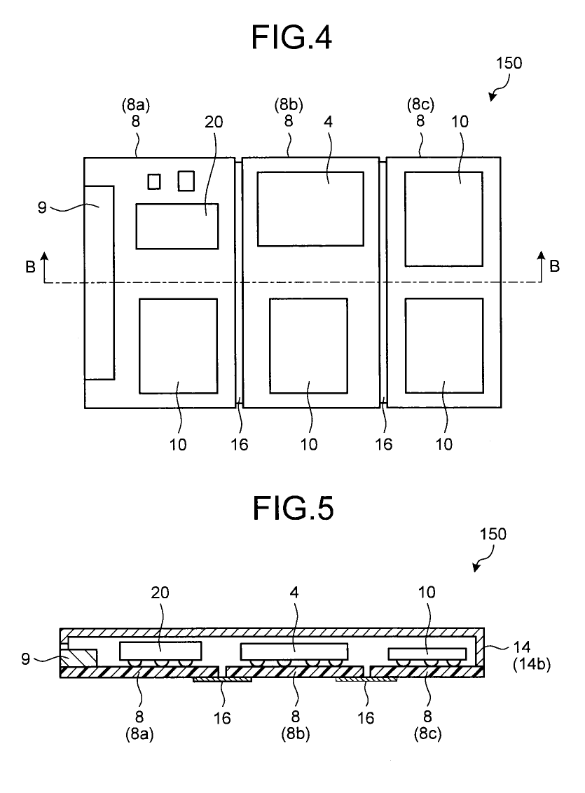

FIG. 4 is a plan view illustrating a schematic configuration of a semiconductor device 150 according to a second embodiment. FIG. 5 is a cross-sectional view along line B-B shown in FIG. 4. The same configuration as the above embodiment is denoted by the same reference numerals and a detailed explanation thereof is omitted.

In the second embodiment, the substrate 8 is divided into three blocks (substrates 8a to 8c). On the substrate 8a, the connector 9 is provided and the DRAM 20 and the NAND memory 10 are mounted. The drive control circuit 4 and the NAND memory 10 are mounted on the substrate 8b. The NAND memories 10 are mounted on the substrate 8c. The combination of the substrates 8a to 8c and the elements to be mounted thereon is not limited to the exemplified one and, for example, the DRAM 20 and the drive control circuit 4 may be mounted on the substrate 8a.

Gaps are provided between the substrates 8a and 8b and between the substrates 8b and 8c. Moreover, the substrates 8a to 8c are connected by TAB tapes 16 attached to a second surface side that is the opposite side of the first surface. Moreover, the wiring layers formed on the substrates 8a to 8c are also electrically connected to each other by the TAB tapes 16.

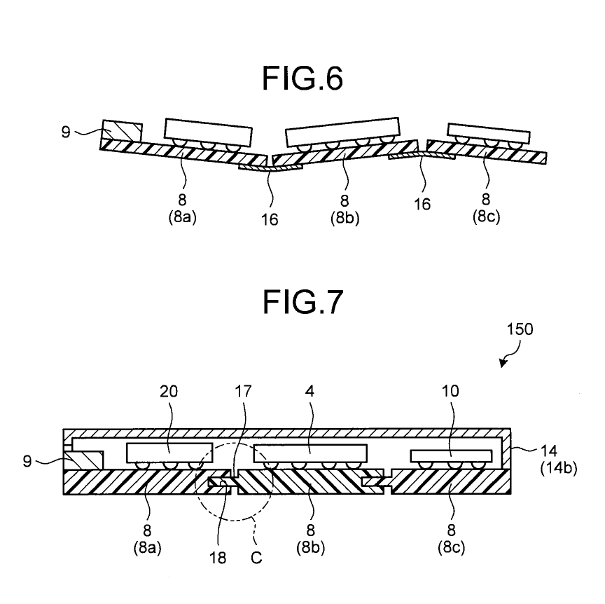

FIG. 6 is a cross-sectional view along line B-B shown in FIG. 4 and is a diagram illustrating a state where an external force is applied to the semiconductor device 150. Because the substrate 8 is divided into three blocks and the divided substrates 8a to 8c are connected to each other by the TAB tapes 16, as shown in FIG. 6, when an external force is applied to the semiconductor device 150, the substrate 8 is deformed at the connection portions, thereby enabling to facilitate absorption of the external force. Therefore, the substrate 8 is not easily damaged and thus the reliability of the semiconductor device 150 can be improved.

Therefore, even when the size and thickness of the semiconductor device 150 are reduced, it is possible to obtain the semiconductor device 150 that is not easily damaged by an external force or the like. For example, even when the semiconductor device 150 is a so-called card shaped semiconductor device 150 in which the planar shape formed by combining the upper case 14b and the substrate 8 has a size of 86 mm×54 mm and which has a height of 2.2 mm or lower, an external force can be easily absorbed by deformation of the substrate 8 by dividing the substrate 8, therefore, it is possible to obtain the semiconductor device 150 that is not easily damaged.

In the second embodiment, because an external force is easily absorbed by deformation of the substrate 8, even when both the upper case 14b and the lower case 14a are not used, the mechanical strength can be ensured in some cases. Thus, in the second embodiment, the configuration is such that the lower case 14a (see also FIG. 2) of the case 14 is not used and only the first surface side of the substrate 8 is covered with the upper case 14b.

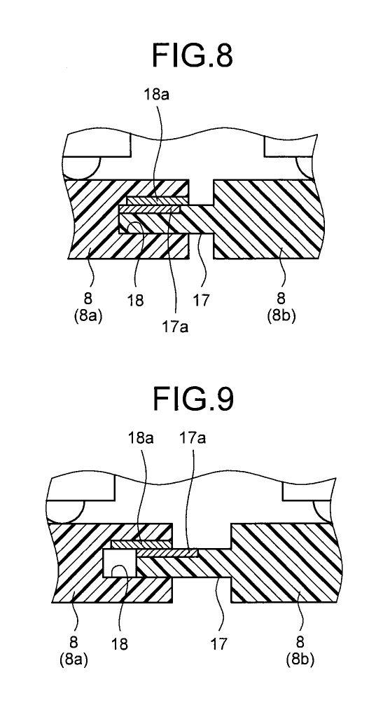

FIG. 7 is a transverse sectional view of the semiconductor device 150 according to a first modified example of the second embodiment. FIG. 8 is a partial enlarged view of a portion C shown in FIG. 7 and is a diagram exemplifying a state where an external force is not applied to the semiconductor device 150. FIG. 9 is a partial enlarged view of the portion C shown in FIG. 7 and is a diagram exemplifying a state where an external force is applied to the semiconductor device 150.

As shown in FIG. 7, in the first modified example, the divided substrates 8a to 8c are connected to each other with connectors. A connector recess portion 18 is formed in the substrate 8a on which the connector 9 is provided. In the connector recess portion 18, a recess-portion-side connector 18a is provided. The recess-portion-side connector 18a is electrically connected to the mounted elements, such as the NAND memory 10 and the DRAM 20, and the connector 9, via the wiring layer of the substrate 8a.

A connector projection portion 17 is formed in a portion, which is opposed to the connector recess portion 18, of the substrate 8b. A projection-portion-side connector 17a is formed in the connector projection portion 17. The projection-portion-side connector 17a is electrically connected to the mounted elements, such as the NAND memory 10 and the drive control circuit 4, via the wiring layer of the substrate 8b.

The connector projection portion 17 is inserted into the connector recess portion 18. In the state where the connector projection portion 17 is inserted into the connector recess portion 18, the recess-portion-side connector 18a and the projection-portion-side connector 17a are in contact with each other. That means that the mounted elements on the substrate 8, and the mounted elements and the connector 9 are electrically connected to each other via the recess-portion-side connector 18a and the projection-portion-side connector 17a by inserting the connector projection portion 17 into the connector recess portion 18. A similar connector-connection is performed also between the substrate 8b and the substrate 8c, however, the configuration is similar to that between the substrate 8a and the substrate 8b, so that the configuration is not illustrated in detail.

Even when the substrate 8 is deformed due to an external force applied to the semiconductor device 150 and the substrate 8a and the substrate 8b are separated from each other from the state shown in FIG. 8, as shown in FIG. 9, contact between the recess-portion-side connector 18a and the projection-portion-side connector 17a is ensured, therefore, the semiconductor device 150 can be stably operated. Moreover, because electrical contact is ensured by the contact between the recess-portion-side connector 18a and the projection-portion-side connector 17a, a failure, such as disconnection, does not easily occur even if the distance between the substrate 8a and the substrate 8b changes.

The distance between the substrates 8a and 8c changes in some cases also when an external force to bend the substrate 8 is applied, however, in this case, in the similar manner to the above explanation, because contact between the recess-portion-side connector 18a and the projection-portion-side connector 17a is ensured, the semiconductor device 150 can be stably operated. Moreover, the capacity of the entire semiconductor device 150 can be easily changed by changing any of the substrates 8a to 8c to a substrate on which the NAND memory 10 of a difference capacity is mounted. That means that the generation and capacity of the NAND memory 10 can be easily changed according to the combination of the divided substrates.

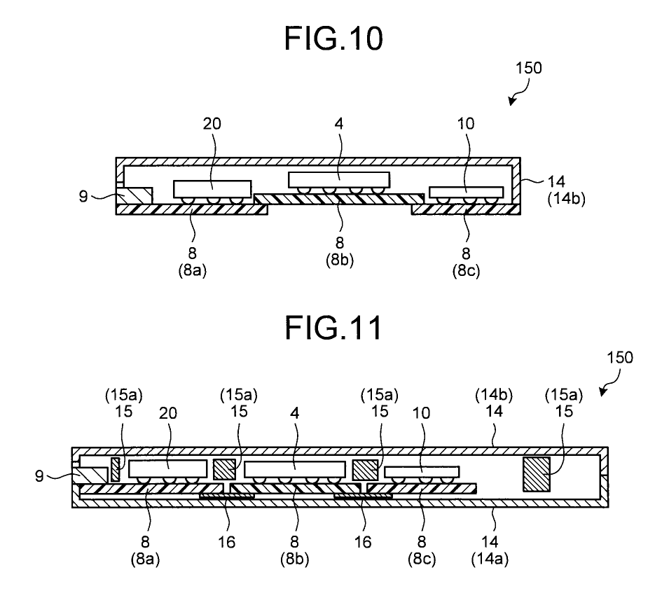

FIG. 10 is a transverse sectional view of a semiconductor device according to a second modified example of the second embodiment. As shown in FIG. 10, in the second modified example, the substrates 8a to 8c are provided to partially overlap each other. Although not shown, with the provision of the connectors 18a and 17a (see also FIGS. 8 and 9) as explained in the above-described first modified example in the overlapping portions of the substrates 8a to 8c, even if the distance between the substrate 8a and the substrate 8b changes, a failure, such as disconnection, does not easily occur, therefore, the reliability of the semiconductor device 150 can be improved.

FIG. 11 is a transverse sectional view of a semiconductor device according to a third modified example of the second embodiment. In the third modified example, as shown in FIG. 11, the substrate 8 (8a to 8c) is divided and the divided substrates are connected to each other by the TAB tapes 16, and moreover, the grid unit 15 composed of the columnar reinforcing units 15a is arranged between the mounted elements, such as the NAND memory 10.

With such a configuration, deformation of the semiconductor device 150 due to an external force is suppressed by the columnar reinforcing units 15a, and moreover, even when the semiconductor device 150 is deformed, disconnection and damage can be suppressed by the deformation of the substrate 8 at the connection portions.

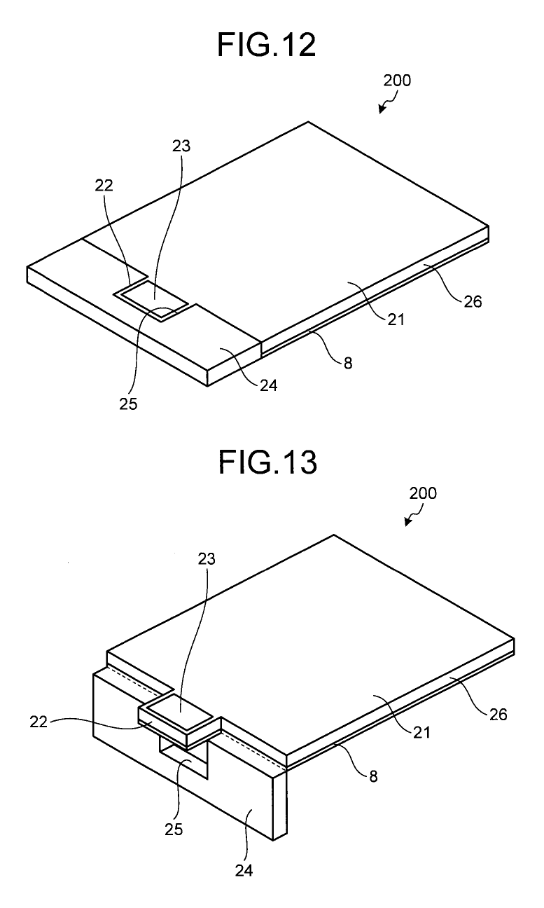

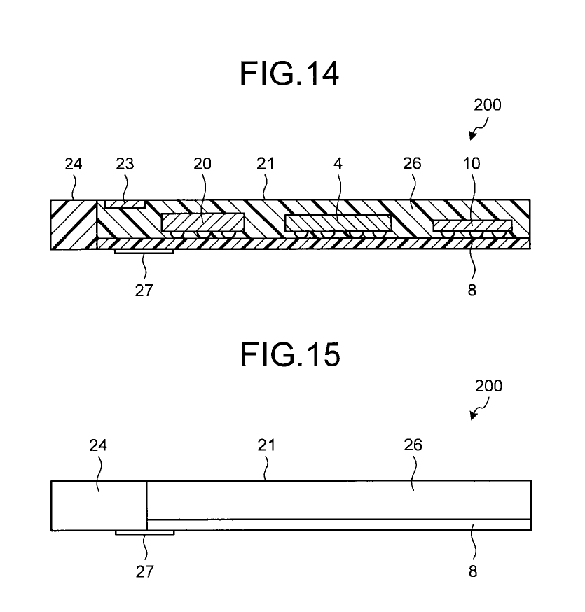

FIG. 12 is an appearance perspective view of a semiconductor device 200 according to a third embodiment. FIG. 13 is an appearance perspective view of the semiconductor device 200 shown in FIG. 12 and is a diagram illustrating a state where a guard is bent. FIG. 14 is a transverse sectional view of the semiconductor device 200 shown in FIG. 12. FIG. 15 is a side view of the semiconductor device 200 shown in FIG. 12. The same configuration as the above embodiment is denoted by the same reference numerals and a detailed explanation thereof is omitted.

As shown in FIG. 14, the semiconductor device 200 according to the third embodiment includes a mold unit 26 formed of synthetic resin to cover the first surface, on which the NAND memory 10 and the like are mounted, of the substrate 8. The mold unit 26 is formed by applying synthetic resin to the first surface of the substrate 8.

As shown in FIGS. 12 and 13, the substrate 8 covered with the mold unit 26 includes a rectangular portion 21 having an approximately rectangular shape in plan view and a projection portion 22 formed to project outward from one side of the rectangular portion 21. An input/output terminal 23 is formed on the surface of the projection portion 22. Information can be input/output to/from the NAND memory 10 and the DRAM 20 via the input/output terminal 23 by bringing the input/output terminal 23 into contact with the terminal on the host apparatus side.

A guard 24 is provided on the side, on which the projection portion 22 is formed, of the rectangular portion 21. A recess portion 25, into which the projection portion 22 is fitted, is formed in the guard 24. The guard 24 is connected to the rectangular portion 21 to be bendable with respect to the rectangular portion 21. Specifically, as shown in FIGS. 14 and 15, the rectangular portion 21 and the guard 24 are connected by using a resin member (hinge unit) 27 on the second surface side to cause the resin member 27 to function as a hinge, thereby enabling the guard 24 to be bendable with respect to the rectangular portion 21. The projection portion 22 is exposed by bending the guard 24 and the projection portion 22 is inserted into the connector or the like on the host apparatus side, whereby the semiconductor device 200 can be used.

As explained above, the mechanical strength of the semiconductor device 200 can be improved by forming the mold unit 26 by applying synthetic resin to the first surface of the substrate 8. Consequently, even when the size and thickness of the semiconductor device 200 are reduced, it is possible to obtain the semiconductor device 200 that is not easily damaged by an external force. For example, even when the semiconductor device 200 is a so-called card shaped semiconductor device 200 in which the planar shape of the entire semiconductor device 200 in a state where the projection portion 22 is fitted into the recess portion 25 has a size of 86 mm×54 mm and which has a height of 2.2 mm or lower, the semiconductor device 200 that is not easily damaged can be obtained by improving the mechanical strength by the mold unit 26.

Moreover, the projection portion 22 projecting from the rectangular portion 21 can be suppressed from being damaged by the projection portion 22 fitting into the recess portion 25 formed in the guard 24. Consequently, the reliability of the semiconductor device 200 can be improved and the lifespan of the product can be extended. Moreover, it is sufficient to bend the guard 24 in the case of using the semiconductor device 200, therefore, the guard 24 is not separated from the rectangular portion 21 and loss of the guard 24 can be prevented.

In the third embodiment, the input/output terminal 23 is explained as a terminal capable of inputting/outputting information to/from the NAND memory 10 and the like by directly bringing the input/output terminal 23 into contact with the terminal on the host apparatus side, however, for example, input/output of information to/from the NAND memory 10 and the like may be enabled without directly bringing the input/output terminal 23 into contact with the host apparatus by configuring the input/output terminal 23 as a terminal for wireless connection.

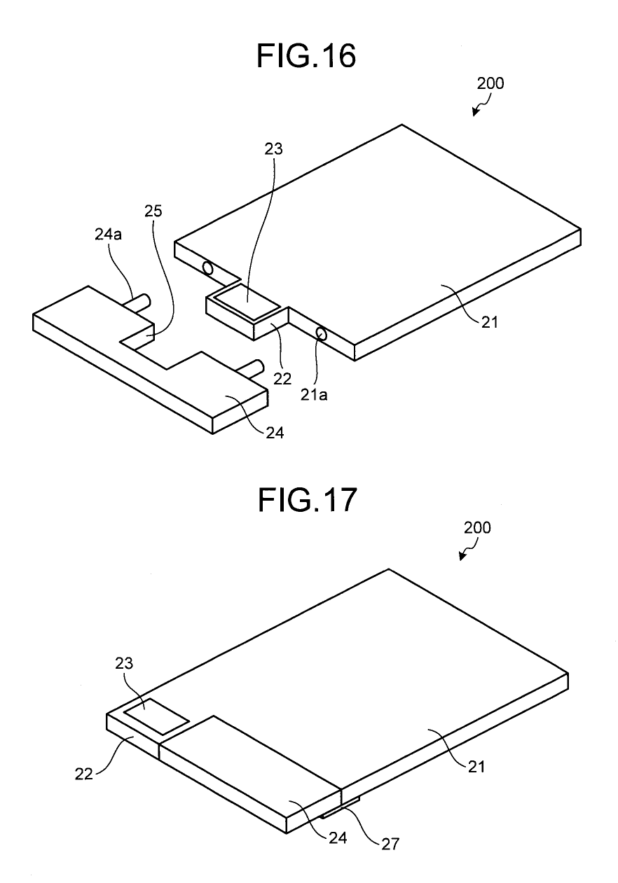

FIG. 16 is an exploded perspective view of a semiconductor device according to a first modified example of the third embodiment. In the present modified example, the rectangular portion 21 and the guard 24 can be separated from each other. Then, as shown in FIG. 16, insertion holes 21a are formed in the surface, which is in contact with the guard 24, of the rectangular portion 21 and insertion projection portions 24a, which are inserted into the insertion holes 21a, are formed on the surface, which is in contact with the rectangular portion 21, of the guard 24. With such a configuration, the guard 24 is attached to the rectangular portion 21 by inserting the insertion projection portions 24a into the insertion holes 21a, therefore, the projection portion 22 can be protected.

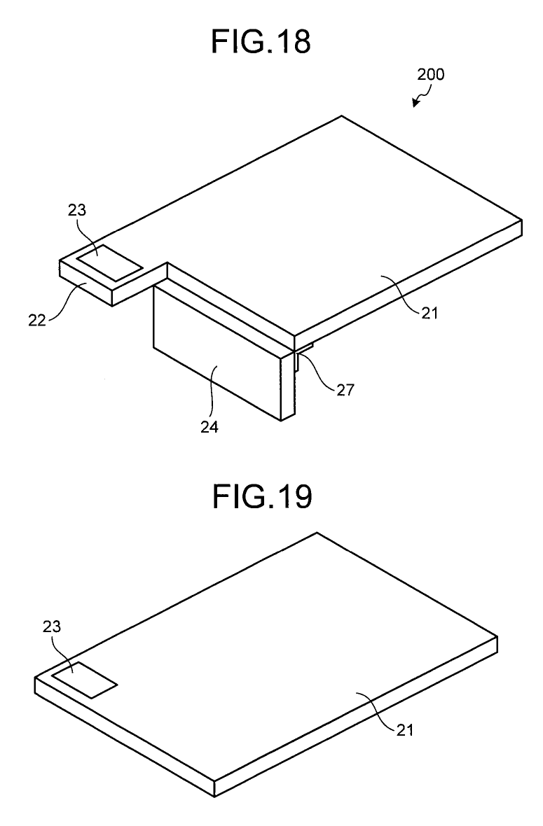

FIG. 17 is an appearance perspective view of the semiconductor device 200 according to a second modified example of the third embodiment. FIG. 18 is an appearance perspective view of the semiconductor device 200 shown in FIG. 17 and is a diagram illustrating a state where the guard 24 is bent. In the second modified example, the projection portion 22 is formed near the end of the rectangular portion 21. The guard 24 is connected to the rectangular portion 21 with the resin member 27 in the similar manner to that shown in FIGS. 14 and 15. In such a manner, the position at which the projection portion 22 is formed may be appropriately changed depending on the specifications or the intended use of the semiconductor device 200.

FIG. 19 is an appearance perspective view of the semiconductor device 200 according to a third modified example of the third embodiment. As shown in FIG. 19, the input/output terminal 23 may be formed without forming a projection portion on the rectangular portion 21. Because the projection portion is not formed, the rectangular portion 21 becomes not easily damaged, therefore, the cost can be suppressed by omitting the guard.

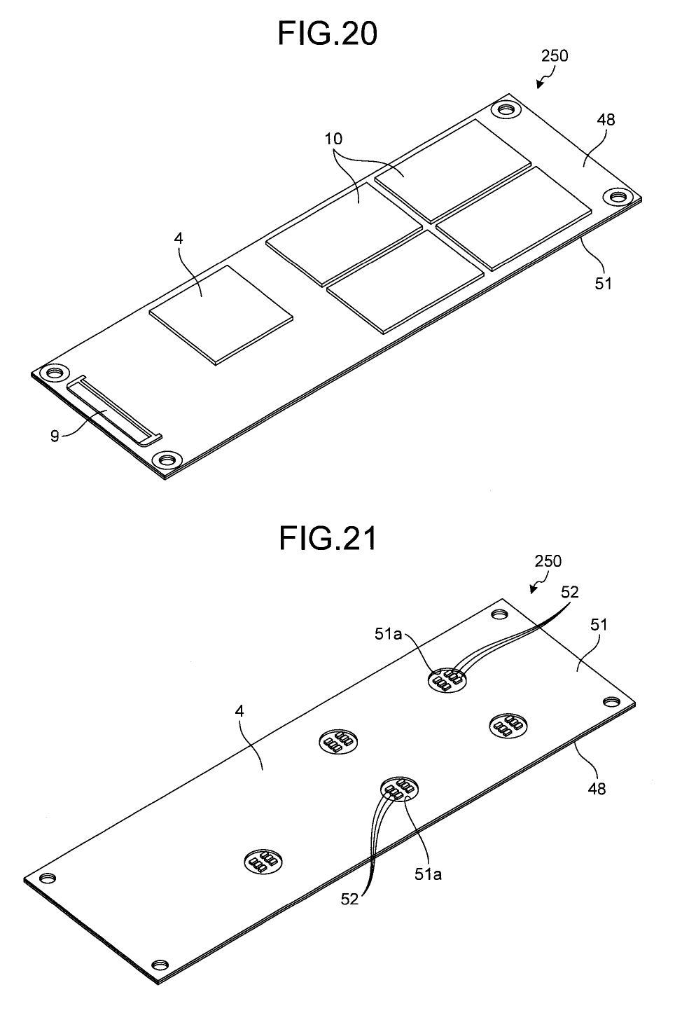

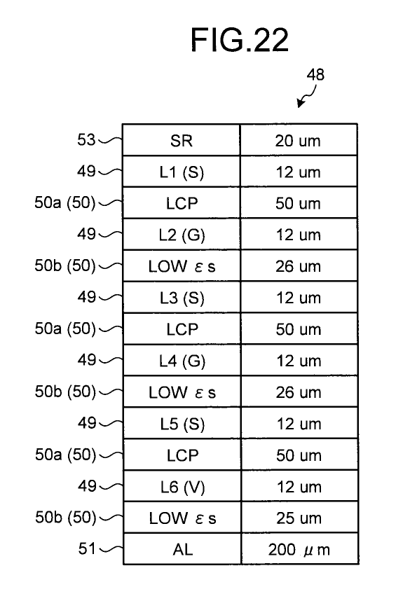

FIG. 20 is an appearance perspective view of a semiconductor device 250 according to a fourth embodiment. FIG. 21 is a perspective view of the semiconductor device 250 shown in FIG. 20 viewed from the second surface side. FIG. 22 is a diagram for explaining a relationship between the layer configuration of the substrate and its thickness. The same configuration as the above embodiment is denoted by the same reference numerals and a detailed explanation thereof is omitted.

In the fourth embodiment, as shown in FIG. 22, a substrate 48 is formed to have a multilayer structure in which conductor layers 49 and insulated layers 50 are stacked. The conductor layer 49 is a layer on which a wiring pattern is formed by using conductor, such as copper. The insulated layer 50 is a layer formed of an insulating material, such as resin, to insulate between the conductor layers 49. A solder resist layer (SR) 53 is formed as a protective film on the first surface side on which the NAND memories 10 are mounted. Six layers (L1 layer to L6 layer) of the conductor layers 49 are formed in the substrate 48 with the insulated layers 50 therebetween. The conductor layers 49 include a layer on which a signal line (S) as a wiring pattern is formed, a layer on which a ground (G) as a wiring pattern is formed, and a layer on which a power line (V) as a wiring pattern is formed. The order of the layer configuration and the like are not limited to the example shown in FIG. 22.

The insulated layers 50 include first insulated layers 50a and second insulated layers 50b. The substrate 48 is thinned compared with the case where the insulated layers 50 include only the first insulated layers 50a by making the second insulated layer 50b thinner than the first insulated layer 50a. For example, in the present embodiment, the first insulated layer 50a has a thickness of about 50 μm and the second insulated layer 50b has a thickness of about 26 μm.

In the substrate 48 having a multilayer structure in which wiring patterns are formed on the conductor layers 49, predetermined electrical characteristics are required for operating the semiconductor device 250 with a desired communication quality. For example, when a wiring pattern is a differential-pair wiring, the target impedance as the predetermined electrical characteristics is about 100Ω. Moreover, when the wiring pattern is a Single-End wiring, the target impedance is 45 to 50Ω.

When a liquid crystal polymer (LOP) is used as the first insulated layer 50a, the relative permittivity thereof becomes about 2.9. As described above, if the thickness of the first insulated layer 50a is set to 50 μm, when the wiring pattern to be formed on the conductor layer 49 is a Single-End wiring, the target impedance of 45 to 50Ω can be achieved by forming the wiring pattern to have a width of 50 μm.

On the other hand, if the substrate 48 is thinned by thinning the first insulated layer 50a having a relative permittivity of about 2.9 to 26 μm, when the wiring pattern to be formed on the conductor layer 49 is a Single-End wiring, it becomes difficult to achieve the target impedance of 45 to 50Ω unless the width of the wiring pattern is set to 25 μm. When the width of the wiring pattern is set to 25 μm, mass production is difficult in terms of processing accuracy and the manufacturing cost.

Therefore, in the present embodiment, the thickness of the second insulated layer 50b is set to 26 μm thinner than the first insulated layer 50a. Then, the second insulated layer 50b is formed of a material having a relative permittivity lower than the first insulated layer 50a. A low dielectric constant adhesion film having a relative permittivity of about 2.4 is used for the second insulated layer 50b.

In such a manner, if the substrate 48 is thinned by forming the second insulated layer 50b by using a material having a relative permittivity lower than the first insulated layer 50a and thinning the thickness of the second insulated layer 50b to 26 μm, when the wiring pattern to be formed on the conductor layer 49 is a Single-End wiring, the target impedance of 45 to 50Ω can be achieved by setting the width of the wiring pattern to 50 μm. If the width of the wiring pattern is 50 μm, mass production can be easily achieved. That means that the substrate can be thinned while obtaining desired electrical characteristics by thinning the second insulated layer 50b having a relative permittivity lower than the first insulated layer 50a. The positions at which the second insulated layers 50b are provided and the number of the second insulated layers 50b are not limited to the example shown in FIG. 22. The positions at which the second insulated layers 50b are provided and the number of the second insulated layers 50b may be changed by changing the order of the conductor layers 49, i.e., the order of the layers on which the signal line (S), the ground (G), the power line (V) are formed.

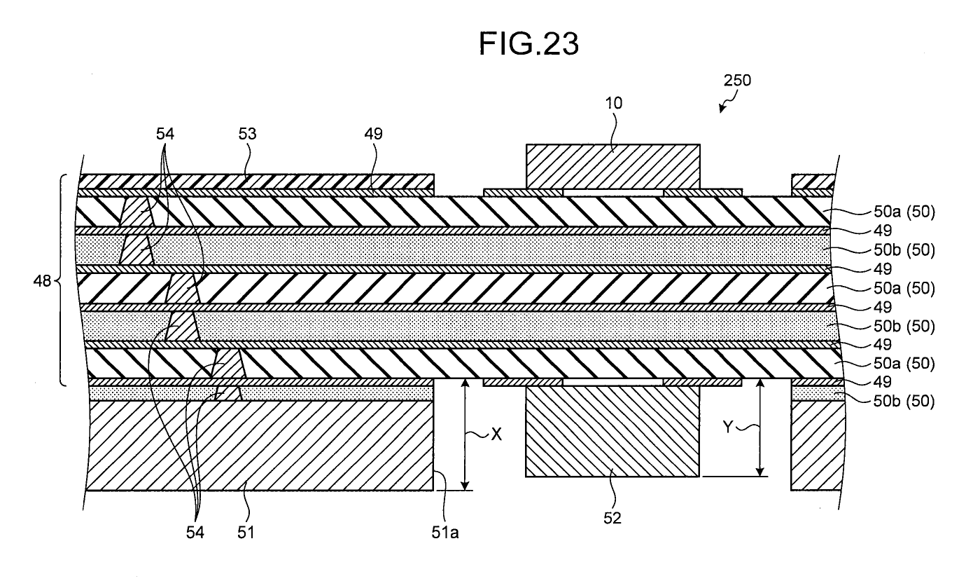

The stacked conductor layers 49 are electrically connected to each other via bumps 54 (see also FIG. 23) provided to penetrate the insulated layers 50. For example, two-layer substrates, in each of which the conductor layer 49 is formed on both sides of the first insulated layer 50a, are prepared. The bump 54 is formed on the conductor layer 49 of one of the two-layer substrates. Then, in a state where the second insulated layer 50b is provided between the two-layer substrate on which the bump 54 is formed and the two-layer substrate on which the bump 54 is not formed, the two two-layer substrates are pressure-bonded to each other, therefore, the bump 54 penetrates the second insulated layer 50b, thereby enabling the conductor layers 49 to be electrically connected to each other. The conductor layers 49 may be electrically connected to each other by forming a via in the insulated layer 50.

As described above, when the substrate 48 is thinned, the strength of the substrate 48 is reduced. Therefore, a reinforcing plate 51 is attached to the second surface side of the substrate 48. The reinforcing plate 51 is, for example, made of metal or resin. The strength of the substrate 48 can be improved by attaching the reinforcing plate 51 made of metal or resin to the substrate 48.

The reinforcing plate 51 is attached to the second surface side of the substrate 48, for example, with a low dielectric constant adhesion film used for the second insulated layer 50b. The reinforcing plate 51 may be attached with double-sided tape or other adhesives.

The conductor layer 49 provided on the most second surface side of the substrate 48 among the conductor layers 49 and the reinforcing plate 51 are electrically connected to each other with the bump 54. For example, the bump 54 is formed on the first surface side of the reinforcing plate 51. Then, in a state where the insulated layer 50 is provided between the reinforcing plate 51 and the substrate 48, they are pressure-bonded to each other, therefore, the bump 54 penetrates the insulated layer 50, thereby enabling to be electrically connected the reinforcing plate 51 and the conductor layer 49. The electrical connection between the reinforcing plate 51 and the conductor layer 49 is not limited to be achieved by using the bump 54. For example, the reinforcing plate 51 and the conductor layer 49 may be electrically connected to each other by using solder.

The reinforcing plate 51 can be used as a ground layer by electrically connecting the reinforcing plate 51 and the conductor layer 49. Moreover, the reinforcing plate 51 can be used as a heat sink that dissipates heat generated in the NAND memory 10 or the like mounted on the first surface side of the substrate 48. In view of the function as the ground layer and the function as a heat sink, the reinforcing plate 51 preferably has a high conductivity. Moreover, in order to improve the strength of the substrate 48, the reinforcing plate 51 is required to have a certain degree of strength. Therefore, when metal is used for the reinforcing plate 51, for example, aluminum or magnesium can be used. Moreover, when resin is used, resin having a high conductivity or resin in which carbon filler is mixed can be used.

A plurality of chip parts 52 is mounted on the second surface side of the substrate 48. The chip part 52 is, for example, a bypass capacitor. The bypass capacitors are electrically connected to the semiconductor elements, such as the NAND memory 10 and the drive control circuit 4, via the conductor layers 49 (wiring patterns). The chip parts 52 are electrically connected to the conductor layer 49 by using solder.

The bypass capacitors are mounted in a region on the back side of a region in which the semiconductor elements are mounted. Consequently, the wiring length between the semiconductor elements and the bypass capacitors can be made short. Openings 51a are formed in the portions of the reinforcing plate 51 that overlap the chip parts 52, such as the bypass capacitor, mounted on the second surface side of the substrate 48. Therefore, the chip parts 52 can be mounted even after attaching the reinforcing plate 51.

Moreover, the openings 51a can be formed in the reinforcing plate 51 in a distributed manner by mounting the bypass capacitors in a region on the back side of a region in which the semiconductor elements are mounted. Reduction in strength of the reinforcing plate 51 due to the formation of the openings 51a can be suppressed compared with the case of collectively forming one large opening in the reinforcing plate 51. Consequently, reduction in strength of the substrate 48 can be suppressed.

FIG. 23 is a partial enlarged cross-sectional view in which a portion on which the chip part 52 is mounted is enlarged. As shown in FIG. 23, the chip part 52 is used, which has a height that does not protrude outside the reinforcing plate 51. In other words, the chip part 52 is used, which has a height Y from the substrate 48 smaller than a depth X down to the substrate 48 of the opening 51a formed in the reinforcing plate 51.

The present embodiment illustrates an example in which the DRAM 20 (see also FIG. 2) is not mounted on the substrate 48, however, it goes without saying that the DRAM 20 may be mounted. In this case, the chip part may be mounted on the back side of a region in which the DRAM 20 is mounted. In this case, it is sufficient to form the opening 51a in a portion of the reinforcing plate 51 that overlap the portion on which the chip part is mounted.

Moreover, if the linear expansion coefficient of the substrate 48 is set to approximately match the linear expansion coefficient of the reinforcing plate 51, the semiconductor device 250 can be prevented from being damaged, for example, due to stripping of the reinforcing plate 51 or the like caused by the difference in linear expansion coefficient at the time of thermal deformation.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate in which conductor layers and insulated layers are stacked alternately;
a semiconductor element mounted on a first surface side of the substrate; and
a reinforcing plate attached to a second surface side that is an opposite side of the first surface of the substrate.

2. The semiconductor device according to claim 1, wherein the insulated layer includes a first insulated layer and a second insulated layer having a relative permittivity lower than the first insulated layer.

3. The semiconductor device according to claim 1, wherein a conductor layer provided on the most second surface side among the conductor layers and the reinforcing plate are electrically connected to each other.

4. The semiconductor device according to claim 3, wherein the conductor layer provided on the most second surface side among the conductor layers and the reinforcing plate are electrically connected to each other via a bump.

5. The semiconductor device according to claim 1, further comprising a chip part mounted on the second surface of the substrate, wherein
an opening is formed in a portion, which overlaps the chip part, of the reinforcing plate.

6. The semiconductor device according to claim 5, wherein
the semiconductor element includes a nonvolatile semiconductor memory element, and
the chip part includes a bypass capacitor and is mounted on a back side of a region in which the nonvolatile semiconductor memory element is mounted.

7. The semiconductor device according to claim 5, wherein
the semiconductor element includes a controller that controls the nonvolatile semiconductor memory element, and
the chip part includes a bypass capacitor and is mounted on a back side of a region in which the controller is mounted.

8. The semiconductor device according to claim 5, wherein a height of the chip part from the second surface is smaller than a depth down to the second surface of an opening formed in the reinforcing plate.

9. The semiconductor device according to claim 1, wherein a linear expansion coefficient of the substrate approximately matches a linear expansion coefficient of the reinforcing plate.

10. The semiconductor device according to claim 1, wherein the reinforcing plate is made of metal.

11. The semiconductor device according to claim 1, wherein the reinforcing plate is made of resin.

12. The semiconductor device according to claim 1, wherein
the second insulated layer is a low dielectric constant adhesion film, and
the substrate is formed by adhering two-layer substrates, in which the conductor layer is provided on both sides of the first insulated layer, to each other with the low dielectric constant adhesion film.

13. The semiconductor device according to claim 1, further comprising a connector that connects the semiconductor element to a host apparatus.

14. A semiconductor device comprising:
a substrate;
a volatile semiconductor memory element mounted on a first surface side of the substrate;
a nonvolatile semiconductor memory element mounted on the first surface side of the substrate;
a controller that is mounted on the first surface side of the substrate and controls the volatile semiconductor memory element and the nonvolatile semiconductor memory element; and
a reinforcing unit that is provided on the first surface side of the substrate and reinforces the substrate.

15. The semiconductor device according to claim 14, further comprising a case surrounding the first surface side of the substrate, wherein
the nonvolatile semiconductor memory element includes a plurality of nonvolatile semiconductor memory elements, and
the reinforcing unit is provided between mounted nonvolatile semiconductor memory elements and has a columnar shape.

16. The semiconductor device according to claim 14, wherein the reinforcing unit is synthetic resin applied to cover the first surface of the substrate.

17. The semiconductor device according to claim 16, wherein
the substrate covered with the synthetic resin includes a rectangular portion having an approximately rectangular shape in plan view and a projection portion formed to project outward from one side of the rectangular portion, wherein
an input/output terminal to the nonvolatile semiconductor memory element is formed on the projection portion,
the semiconductor device further includes a guard in which a recess portion, into which the projection portion is fitted, is formed and which protects the projection portion, and
the guard is connected to the substrate to be bendable with respect to the guard.

18. The semiconductor device according to claim 14, wherein
a wiring layer is formed on the substrate and the substrate is divided into a plurality of substrates,
the semiconductor device further includes a connection portion that connects divided substrates to each other, and
wiring layers of the divided substrates are connected to each other via the connection portion.

19. The semiconductor device according to claim 18, wherein the connection portion is a TAB tape.
